(19) United States
(12) Patent Application Publication
(10) Pub. No.: US 2023/0262888 A1
(43) Pub. Date: Aug. 17, 2023

(54) MULTILAYER STRUCTURE AND METHOD FOR MANUFACTURING THE SAME

(71) Applicant: Murata Manufacturing Co., Ltd., Kyoto-fu (JP)

(72) Inventor: Hiromichi TANAKA, Nagaokakyo-shi (JP)

(21) Appl. No.: 18/303,648

(22) Filed: Apr. 20, 2023

Related U.S. Application Data
(63) Continuation of application No. PCT/JP2021/038730, filed on Oct. 20, 2021.

(30) Foreign Application Priority Data
Oct. 22, 2020 (JP) 2020-177476

(51) Int. Cl. H05K 1/02; H05K 3/46

(52) U.S. Cl. CPC H05K 1/0298; H05K 3/4664; H05K 2201/0338; H05K 2201/0347; H05K 2201/09672

(57) ABSTRACT

A multilayer structure having a main surface includes: a first conductor extending in parallel with the main surface; a second conductor extending in parallel with the main surface and disposed at a different position from the first conductor with respect to a thickness direction of the multilayer structure; and a third conductor having a shape extending in at least any direction as seen in a direction perpendicular to the main surface. In a range higher than a lower end of the third conductor and lower than an upper end of the third conductor in the thickness direction of the multilayer structure, at least a part of the first conductor is included and at least a part of the second conductor is included.

### CROSS REFERENCE TO RELATED APPLICATION

This is a continuation of International Application No. PCT/JP2021/038730 filed on Oct. 20, 2021 which claims priority from Japanese Patent Application No. 2020-177476 filed on Oct. 22, 2020. The contents of these applications are incorporated herein by reference in their entireties.

### BACKGROUND OF THE DISCLOSURE

### Field of the Disclosure

The present disclosure relates to a multilayer structure and a method for manufacturing the same.

### Description of the Related Art

Japanese Patent Laying-Open No. 2000-031328 (PTL 1) discloses “ceramic multilayer wiring board.” This ceramic multilayer wiring board includes a capacitor located near the front surface that forms an IC chip mounting surface, and includes a conductor layer located near the back surface and made of a material substantially identical to the material for an electrode layer of the capacitor. PTL 1 discloses that non-uniformity of the firing shrinkage is balanced in the thickness direction of the substrate, and the ceramic multilayer wiring board with less warp can be achieved.

PTL 1: Japanese Patent Laying-Open No. 2000-031328

### BRIEF SUMMARY OF THE DISCLOSURE

To produce a multilayer wiring board as disclosed in PTL 1, sheets are stacked and fired. During the firing, the sheets shrink to cause displacement of interconnection layers around the sheets, resulting in a problem that unintended parasitic inductance and/or parasitic capacitance is generated.

In view of the above, a possible benefit of the present disclosure is to provide a multilayer structure and a method for manufacturing the multilayer structure that enable suppression of generation of unintended parasitic components during firing.

In order to achieve the possible benefit, a multilayer structure based on the present disclosure is a multilayer structure having a main surface, and the multilayer structure includes: a first conductor extending in parallel with the main surface; a second conductor extending in parallel with the main surface and disposed at a different position from the first conductor with respect to a thickness direction of the multilayer structure; and a third conductor that has a shape extending in at least any direction as seen in a direction perpendicular to the main surface, and is disposed at a position besides both the first conductor and the second conductor. As seen in a cross section perpendicular to the main surface, in a range higher than a lower end of the third conductor and lower than an upper end of the third conductor, at least a part of the first conductor is included and at least a part of the second conductor is included.

According to the present disclosure, the presence of the third conductor suppresses deformation of the first conductor and the second conductor, and accordingly enables suppression of generation of unintended parasitic components during firing.

### BRIEF DESCRIPTION OF THE SEVERAL VIEWS OF THE DRAWINGS

FIG. 1 is a plan view of a multilayer structure according to Embodiment 1 based on the present disclosure.

FIG. 2 is a cross-sectional view along line II-II in FIG. 1 as seen in the direction of the arrows.

FIG. 3 is a plan view of a multilayer structure according to Embodiment 2 based on the present disclosure.

FIG. 4 is a cross-sectional view along line IV-IV in FIG. 3 as seen in the direction of the arrows.

FIG. 5 is a cross-sectional view of a first modification of the multilayer structure according to Embodiment 2 based on the present disclosure.

FIG. 6 is a cross-sectional view of a second modification of the multilayer structure according to Embodiment 2 based on the present disclosure.

FIG. 7 is a cross-sectional view of a multilayer structure according to Embodiment 3 based on the present disclosure.

FIG. 8 is a cross-sectional view of a multilayer structure according to Embodiment 4 based on the present disclosure.

FIG. 9 is a cross-sectional view of a multilayer structure according to Embodiment 5 based on the present disclosure.

FIG. 10 is a cross-sectional view of a multilayer structure according to Embodiment 6 based on the present disclosure.

FIG. 11 is a cross-sectional view along line XI-XI in FIG. 10 as seen in the direction of the arrows.

FIG. 12 is a cross-sectional view along line XII-XII in FIG. 10 as seen in the direction of the arrows.

FIG. 13 is a cross-sectional view of a multilayer structure according to Embodiment 7 based on the present disclosure.

FIG. 14 is a cross-sectional view along line XIV-XIV in FIG. 13 as seen in the direction of the arrows.

FIG. 15 is a cross-sectional view along line XV-XV in FIG. 13 as seen in the direction of the arrows.

FIG. 16 is a plan view of a multilayer structure according to Embodiment 8 based on the present disclosure.

FIG. 17 is a first illustration of a method for manufacturing a multilayer structure according to Embodiment 9 based on the present disclosure.

FIG. 18 is a second illustration of the method for manufacturing a multilayer structure according to Embodiment 9 based on the present disclosure.

FIG. 19 is a third illustration of the method for manufacturing a multilayer structure according to Embodiment 9 based on the present disclosure.

FIG. 20 is a fourth illustration of the method for manufacturing a multilayer structure according to Embodiment 9 based on the present disclosure.

FIG. 21 is a fifth illustration of the method for manufacturing a multilayer structure according to Embodiment 9 based on the present disclosure.

FIG. 22 is a sixth illustration of the method for manufacturing a multilayer structure according to Embodiment 9 based on the present disclosure.

FIG. 23 is a seventh illustration of the method for manufacturing a multilayer structure according to Embodiment 9 based on the present disclosure.

FIG. 24 is an eighth illustration of the method for manufacturing a multilayer structure according to Embodiment 9 based on the present disclosure.

FIG. 25 is a ninth illustration of the method for manufacturing a multilayer structure according to Embodiment 9 based on the present disclosure.

FIG. 26 is a 10th illustration of the method for manufacturing a multilayer structure according to Embodiment 9 based on the present disclosure.

FIG. 27 is an 11th illustration of the method for manufacturing a multilayer structure according to Embodiment 9 based on the present disclosure.

FIG. 28 is a 12th illustration of the method for manufacturing a multilayer structure according to Embodiment 9 based on the present disclosure.

FIG. 29 is a 13th illustration of the method for manufacturing a multilayer structure according to Embodiment 9 based on the present disclosure.

FIG. 30 is a 14th illustration of the method for manufacturing a multilayer structure according to Embodiment 9 based on the present disclosure.

FIG. 31 is a 15th illustration of the method for manufacturing a multilayer structure according to Embodiment 9 based on the present disclosure.

FIG. 32 is a 16th illustration of the method for manufacturing a multilayer structure according to Embodiment 9 based on the present disclosure.

FIG. 33 is a 17th illustration of the method for manufacturing a multilayer structure according to Embodiment 9 based on the present disclosure.

FIG. 34 is an 18th illustration of the method for manufacturing a multilayer structure according to Embodiment 9 based on the present disclosure.

FIG. 35 is a 19th illustration of the method for manufacturing a multilayer structure according to Embodiment 9 based on the present disclosure.

FIG. 36 is a 20th illustration of the method for manufacturing a multilayer structure according to Embodiment 9 based on the present disclosure.

FIG. 37 is a cross-sectional view of a multilayer structure according to Embodiment 10 based on the present disclosure.

FIG. 38 is a cross-sectional view along line XXXVIII-XXXVIII in FIG. 37 as seen in the direction of the arrows.

FIG. 39 is a cross-sectional view along line XXXIX-XXXIX in FIG. 37 as seen in the direction of the arrows.

FIG. 40 is an illustration of a multilayer structure according to Embodiment 11 based on the present disclosure.

FIG. 41 is an illustration of an approach taken when a third conductor in the multilayer structure has a rounded shape according to Embodiment 11 based on the present disclosure.

FIG. 42 is an illustration of a preferred condition for the multilayer structure according to Embodiment 11 based on the present disclosure.

### DETAILED DESCRIPTION OF THE DISCLOSURE

Any dimensional ratio shown in the drawings does not necessarily represent the exact actual dimensional ratio, but may be exaggerated for convenience of illustration. In the following description, the concept “top/upper” or “bottom/lower” mentioned herein does not necessarily refer to the exact “top/upper” or “bottom/lower,” but may refer, in a relative sense, to “top/upper” or “bottom/lower” of a posture shown in a drawing(s).

### Embodiment 1

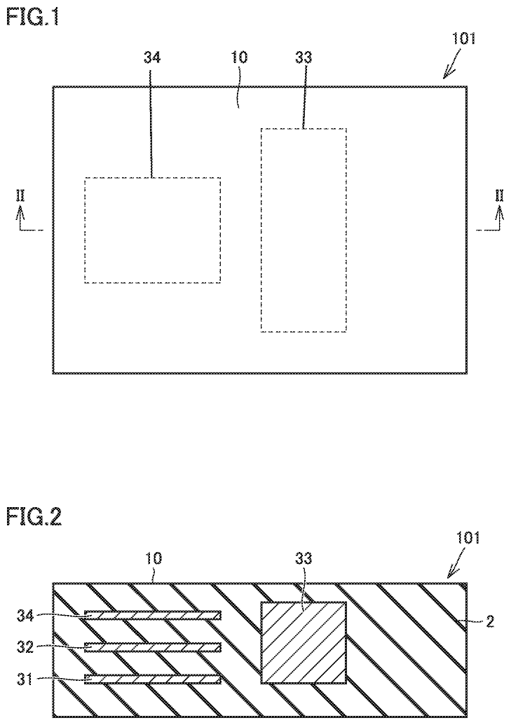

Referring to FIGS. 1 to 2, a multilayer structure according to Embodiment 1 based on the present disclosure is described. FIG. 1 shows a plan view of a multilayer structure 101 according to the present embodiment. FIG. 2 shows a cross-sectional view along line II-II in FIG. 1 as seen in the direction of the arrows. In an example illustrated here, multilayer structure 101 is a multilayer substrate. Specifically, multilayer structure 101 is a ceramic multilayer substrate. More specifically, multilayer structure 101 is formed by stacking and firing ceramic green sheets. Multilayer structure 101 includes an electrical insulator 2. Insulator 2 is formed by firing stacked ceramic green sheets to thereby integrate the sheets into the insulator. Multilayer structure 101 includes structural components such as interconnection located on a surface or inside and made of electrical conductor.

Multilayer structure 101 has a main surface 10. Multilayer structure 101 includes a first conductor 31, a second conductor 32, and a third conductor 33. First conductor 31 extends in parallel with main surface 10. Second conductor 32 extends in parallel with main surface 10 and disposed at a position different from first conductor 31 with respect to the thickness direction of multilayer structure 101. “Parallel” is not herein limited to the strict meaning of parallel, but allows some distortion, displacement, and/or error. In other words, “parallel” includes a substantially parallel state. Third conductor 33 has a shape extending in at least any direction as seen in the direction perpendicular to main surface 10. Third conductor 33 is disposed at a position beside both first conductor 31 and second conductor 32. Regarding third conductor 33, “extending in any direction” means that third conductor 33 has a shape of which longitudinal direction is any direction other than the direction perpendicular to main surface 10. As shown in FIG. 2, as seen in a cross section perpendicular to main surface 10, at least a part of first conductor 31 is included and at least a part of second conductor 32 is included, in a range higher than the lower end of third conductor 33 and lower than the upper end of third conductor 33, in the thickness direction of multilayer structure 101.

First conductor 31 may extend in the direction perpendicular to the plane of FIG. 2. The same applies as well to second conductor 32 and third conductor 33.

During firing, shrinkage of an electrical conductor is less than that of a ceramic green sheet, and therefore, the presence of third conductor 33 suppresses deformation of its surrounding. In the present embodiment, as seen in a cross section perpendicular to main surface 10, first conductor 31 is at least partially included and second conductor 32 is at least partially included, in the range higher than the lower end of third conductor 33 and lower than the upper end of third conductor 33, and therefore, deformation of first conductor 31 and second conductor 32 is also suppressed. Thus, generation of unintended parasitic components during firing can be suppressed.

In the present embodiment, a fourth conductor 34 is also disposed near third conductor 33. Thus, any conductor other than first conductor 31 and second conductor 32 may also be disposed.

In connection with the present embodiment, multilayer structure 101 that is a ceramic multilayer substrate is described, merely by way of example. Multilayer structure 101 may also be a resin multilayer substrate. Specifically, insulator 2 may be ceramic or may be resin. In the case where the multilayer structure is a resin multilayer substrate instead of the ceramic multilayer substrate, “ceramic green sheets” in the description herein of the ceramic multilayer substrate may be replaced with “uncured resin sheets” and “firing” may be replaced with “curing.”

As illustrated in connection with the present embodiment, preferably first conductor 31 and second conductor 32 at least partially overlap each other as seen in the direction perpendicular to main surface 10. When this configuration is employed, a parasitic component generated between first conductor 31 and second conductor 32 should be noted. The presence of third conductor 33, however, makes it possible to suppress unwanted variation of the parasitic component generated between first conductor 31 and second conductor 32, which is therefore advantageous.

first conductor 31 or second conductor 32 may be coplanar with the lower surface of third conductor 33. On the contrary, the upper surface of first conductor 31 or second conductor 32 may be coplanar with the upper surface of third conductor 33.

### Embodiment 2

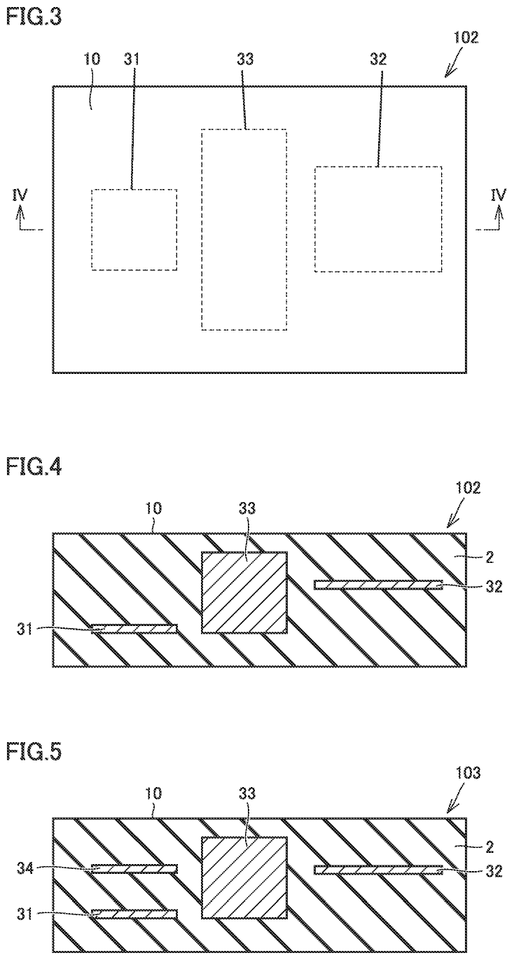

Referring to FIGS. 3 to 4, a multilayer structure according to Embodiment 2 based on the present embodiment is described. FIG. 3 shows a plan view of a multilayer structure 102 according to the present embodiment. FIG. 4 shows a cross-sectional view along line IV-IV in FIG. 3 as seen in the direction of the arrows.

In multilayer structure 101 shown in FIG. 1, first conductor 31 and second conductor 32 are disposed on the same side with respect to third conductor 33. Like multilayer structure 102 shown in FIGS. 3 and 4, first conductor 31 and second conductor 32 may be disposed on different sides with respect to third conductor 33. In other words, first conductor 31 and second conductor 32 may have a positional relation to locate third conductor 33 between the first and second conductors.

The present embodiment can also achieve advantageous effects similar to those of Embodiment 1.

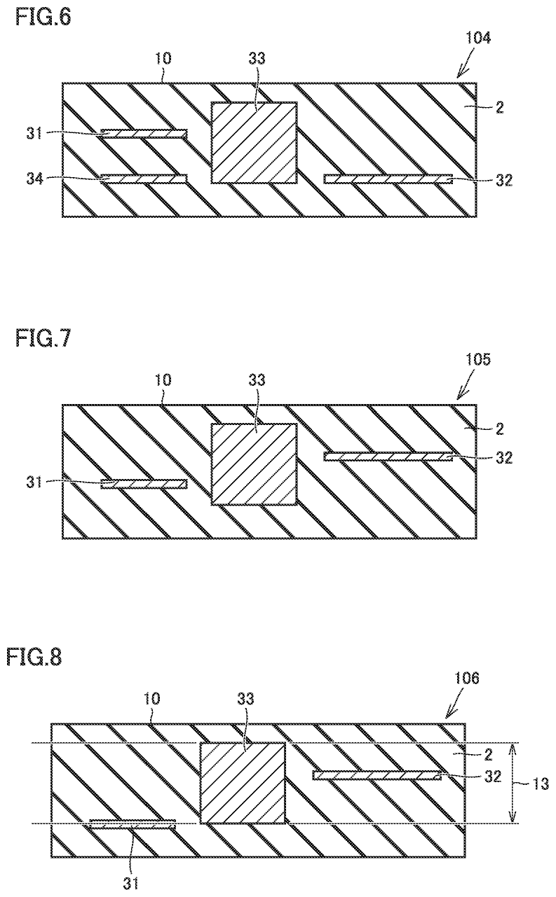

Like a multilayer structure 103 shown in FIG. 5, another conductor, i.e., fourth conductor 34, may be located at the same level as second conductor 32. While multilayer structure 103 includes fourth conductor 34 located higher than first conductor 31, fourth conductor 34 may be located lower than first conductor 31 like a multilayer structure 104 shown in FIG. 6.

While first conductor 31 and fourth conductor 34 are located to face each other in the thickness direction and thereby function as a capacitor, the configuration illustrated in connection with the present embodiment can be employed to suppress unwanted variation of the parasitic component generated between first conductor 31 and fourth conductor 34, which is therefore advantageous.

### Embodiment 3

Referring to FIG. 7, a multilayer structure according to Embodiment 3 based on the present disclosure is described. FIG. 7 shows a cross-sectional view of a multilayer structure 105 according to the present embodiment.

The basic configuration of multilayer structure 105 is similar to the one described in connection with the foregoing embodiments. In multilayer structure 105 as seen in a cross section perpendicular to main surface 10, first conductor 31 is entirely included and second conductor 32 is entirely included in a range higher than the lower end of third conductor 33 and lower than the upper end of third conductor 33 in the thickness direction of multilayer structure 105. In an example illustrated here, the lower surface of first conductor 31 is located higher than the lower surface of third conductor 33, and the upper surface of second conductor 32 is located lower than the upper surface of third conductor 33.

In the present embodiment, respective positions of first conductor 31 and second conductor 32 in the height direction are those as described above, and therefore, the presence of third conductor 33 produces a significant effect of suppressing deformation, and therefore, generation of unintended parasitic components during firing can more effectively be suppressed.

In the present embodiment, second conductor 32 is located higher than first conductor 31, which, however, is given merely by way of example, and their positional relation may be opposite to the above-described one. If first conductor 31 is located higher than second conductor 32, the upper surface of first conductor 31 may be located lower than the upper surface of third conductor 33 and the lower surface of second conductor 32 may be located higher than the lower surface of third conductor 33.

### Embodiment 4

Referring to FIG. 8, a multilayer structure according to Embodiment 4 based on the present disclosure is described. FIG. 8 shows a cross-sectional view of a multilayer structure 106 according to the present embodiment. The basic configuration of multilayer structure 106 is similar to the one described in connection with the foregoing embodiments. As shown in FIG. 8, as seen in a cross section perpendicular to main surface 10, a part of first conductor 31 is included inside a range 13 higher than the lower end of third conductor 33 and lower than the upper end of third conductor 33 in the thickness direction of multilayer structure 106. The other part of first conductor 31 is located outside range 13. Second conductor 32 is entirely included in range 13. Thus, one of first conductor 31 and second conductor 32 may be located partially outside this range. Instead of first conductor 31, second conductor 32 may be located partially outside range 13. A part of first conductor 31 may be located outside range 13 and a part of second conductor 32 may also be located outside range 13.

The present embodiment can also achieve, to some extent, the advantageous effects described above in connection with Embodiment 1.

### Embodiment 5

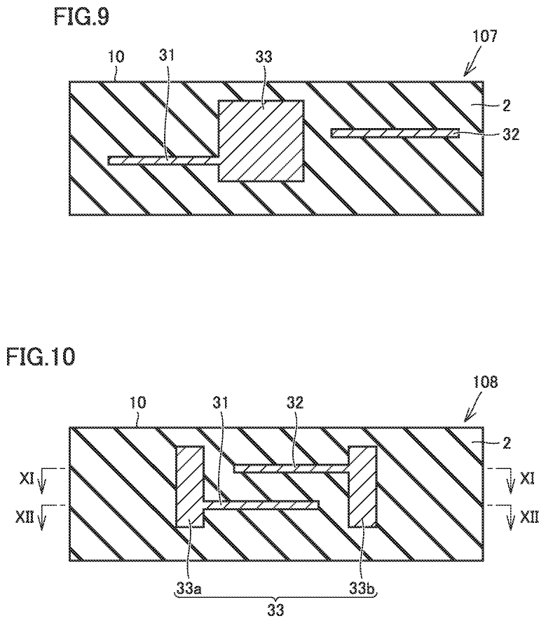

Referring to FIG. 9, a multilayer structure according to Embodiment 5 based on the present disclosure is described. FIG. 9 shows a cross-sectional view of a multilayer structure 107 according to the present embodiment. The basic configuration of multilayer structure 107 is similar to the one described in connection with the foregoing embodiments.

In multilayer structure 107, at least one of first conductor 31 and second conductor 32 is connected to third conductor 33.

The present embodiment can also achieve the advantageous effects as described above in connection with Embodiment 1.

### Embodiment 6

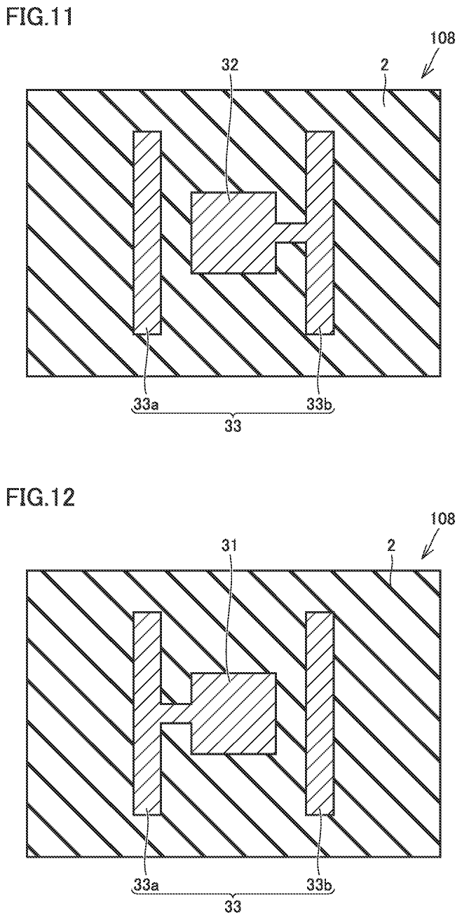

Referring to FIGS. 10 to 12, a multilayer structure according to Embodiment 6 based on the present disclosure is described. FIG. 10 shows a cross-sectional view of a multilayer structure 108 according to the present embodiment. The basic configuration of multilayer structure 108 is similar to the one described in connection with the foregoing embodiments. It should be noted, however, third conductor 33 of multilayer structure 108 is made up of two separate parts. Specifically, third conductor 33 includes a part 33a and a part 33b. FIG. 11 shows a cross-sectional view along line XI-XI in FIG. 10 as seen in the direction of the arrows. FIG. 12 shows a cross-sectional view along line XII-XII in FIG. 10 as seen in the direction of the arrows.

Second conductor 32 is disposed higher than first conductor 31. At least a part of second conductor 32 overlaps at least a part of first conductor 31. First conductor 31 is connected to part 33a. Second conductor 32 is connected to part 33b.

The present embodiment can also achieve the advantageous effects as described above in connection with Embodiment 1.

### Embodiment 7

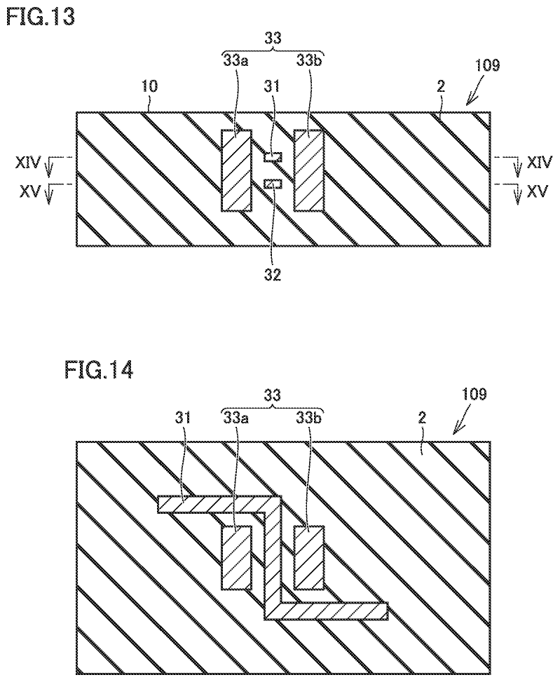

Referring to FIGS. 13 to 15, a multilayer structure according to Embodiment 7 based on the present disclosure is described. FIG. 13 shows a cross-sectional view of a multilayer structure 109 according to the present embodiment. The basic configuration of multilayer structure 109 is similar to the one described in connection with the foregoing embodiments. It should be noted, however, third conductor 33 of multilayer structure 109 is made up of two separate parts. Specifically, third conductor 33 includes a part 33a and a part 33b. FIG. 14 shows a cross-sectional view along line XIV-XIV in FIG. 13 as seen in the direction of the arrows. FIG. 15 shows a cross-sectional view along line XV-XV in FIG. 13 as seen in the direction of the arrows. As seen in a plan view, first conductor 31 and second conductor 32 are each in the form of a bent line. An intermediate part of first conductor 31 and an intermediate part of second conductor 32 overlap each other. The portion where the intermediate part of first conductor 31 and the intermediate part of second conductor 32 overlap each other is located between parts 33a and 33b of third conductor 33.

The present embodiment can also achieve the advantageous effects as described above in connection with Embodiment 1.

### Embodiment 8

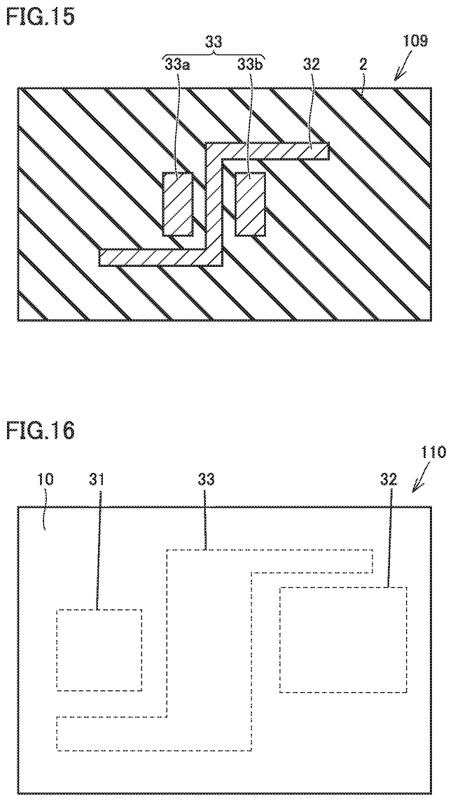

Referring to FIG. 16, a multilayer structure according to Embodiment 8 based on the present disclosure is described. FIG. 16 shows a plan view of a multilayer structure 110 according to the present embodiment. As seen in the plan view, third conductor 33 is in the form of a bent line. First conductor 31 and second conductor 32 are located so that a part of third conductor 33 is located between the first and second conductors. The configuration as seen in a cross-sectional view may be any of respective configurations shown in FIGS. 4, 6, and 7.

The present embodiment can also achieve the advantageous effects as described above in connection with Embodiment 1.

### Embodiment 9

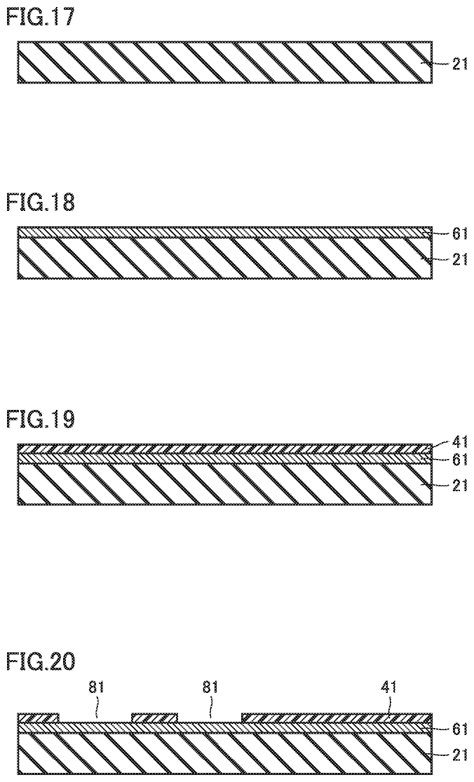

Referring to FIGS. 17 to 36, a method for manufacturing a multilayer structure according to Embodiment 9 based on the present disclosure is described.

The method is a method for manufacturing the multilayer structure described above in connection with any of the foregoing embodiments, or a method for manufacturing a multilayer structure described later herein in connection with Embodiment 10 or any subsequent embodiment. The method for manufacturing a multilayer structure according to the present embodiment includes the steps of: forming a first base metal layer on an upper surface of a first insulating layer; depositing a first resist film on an upper side of the first base metal layer; partially exposing the first base metal layer by forming a first opening in the first resist film; forming, by plating, a first conductive layer on a part of an upper surface of the first base metal layer that is exposed from the first opening; removing the first resist film; removing a part of the first base metal layer that is not covered with the first conductive layer; depositing a second resist film on only a part of the first conductive layer; forming a second insulating layer that covers the first insulating layer and the first conductive layer and exposes the second resist film; forming, in the second insulating layer, a second opening that exposes a part of the first conductive layer, by removing the second resist film; forming a second base metal layer on an upper surface of the second insulating layer; depositing a third resist film on an upper side of the second base metal layer; forming, in the third resist film, a third opening corresponding to the second opening, and a fourth opening in another region; forming, by plating, a second conductive layer on a part of an upper surface of the first conductive layer that is exposed through the third opening and the second opening and forming, by plating, a third conductive layer on a part of an upper surface of the second base metal layer that is exposed from the fourth opening; removing the third resist film; removing a part of the second base metal layer that is not covered with the third conductive layer; and forming a third insulating layer that covers the second insulating layer, the second conductive layer, and the third conductive layer. This manufacturing method is the so-called build-up method. Each step of the manufacturing method is described in detail hereinafter with reference to the drawings.

As shown in FIG. 17, initially a first insulating layer 21 is prepared. As shown in FIG. 18, the step of forming a first base metal layer 61 on an upper surface of first insulating layer 21 is performed. First base metal layer 61 may for example be a film having a double layer structure in which a Cu film is laid on a Ti film. First base metal layer 61 may be formed by sputtering, for example. First base metal layer 61 has a thickness of less than 1 μm, for example.

As shown in FIG. 19, the step of depositing a first resist film 41 on an upper side of first base metal layer 61 is performed. First resist film 41 may for example be a dry resist film. As shown in FIG. 20, the step of partially exposing first base metal layer 61 by forming a first opening 81 in first resist film 41 is performed. First opening 81 may be formed by exposure and development.

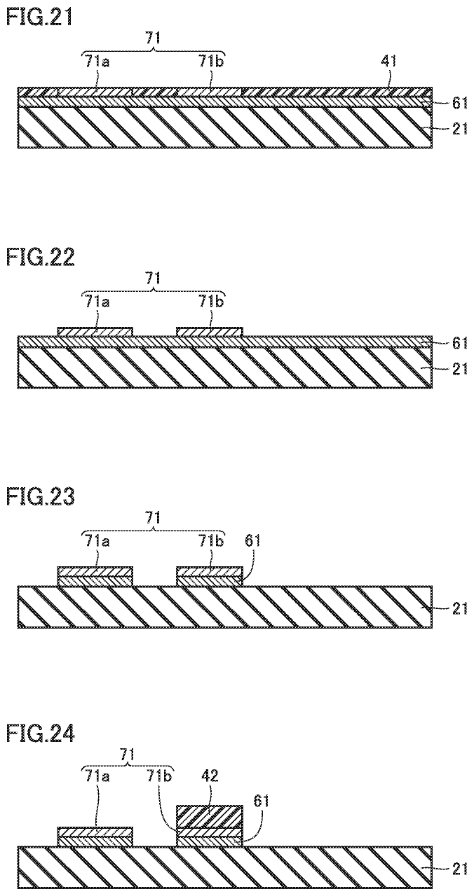

As shown in FIG. 21, the step of forming, by plating, a first conductive layer 71 on a part of an upper surface of first base metal layer 61 that is exposed from first opening 81 is performed. First conductive layer 71 includes a part 71a and a part 71b. As shown in FIG. 22, the step of removing first resist film 41 is performed. As shown in FIG. 23, the step of removing a part of first base metal layer 61 that is not covered with first conductive layer 71 is performed.

As shown in FIG. 24, the step of depositing a second resist film 42 on only a part of first conductive layer 71 is performed. Here, the part of first conductive layer 71 is part 71b.

As shown in FIG. 25, the step of forming a second insulating layer 22 that covers first insulating layer 21 and first conductive layer 71 and exposes second resist film 42 is performed. Before this step is performed, part 71a of first conductive layer 71 is exposed. This step is performed to cover part 71a with second insulating layer 22.

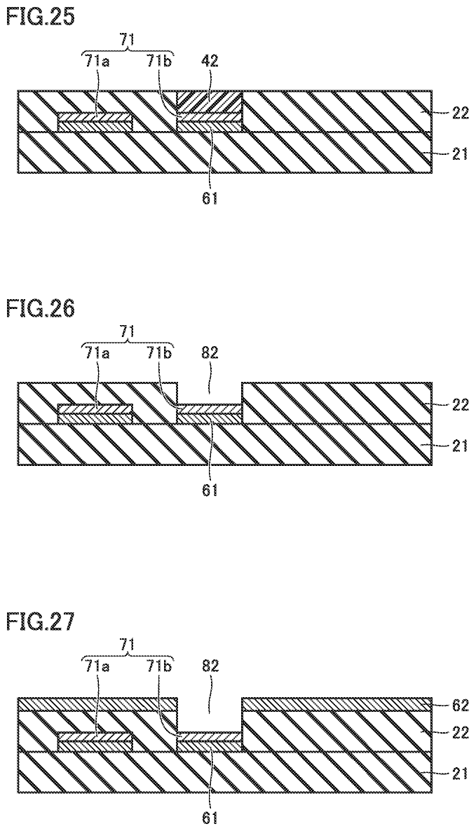

As shown in FIG. 26, the step of forming, in second insulating layer 22, a second opening 82 that exposes a part of first conductive layer 71, by removing second resist film 42, is performed. Here, part 71b that is a part of first conductive layer 71 is exposed through second opening 82.

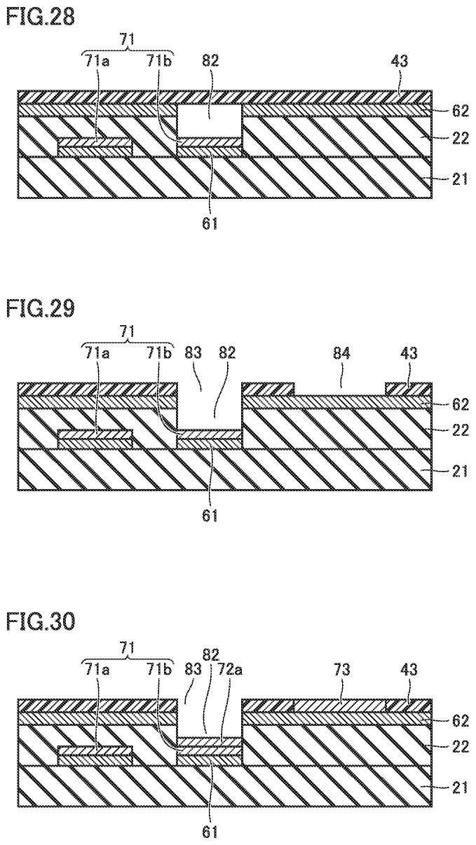

As shown in FIG. 27, the step of forming a second base metal layer 62 on an upper surface of second insulating layer 22 is performed. As shown in FIG. 28, the step of depositing a third resist film 43 on an upper side of second base metal layer 62 is performed. In an example illustrated here, third resist film 43 in the form of a sheet is prepared and mounted on the upper side of second base metal layer 62. As shown in FIG. 29, the step of forming, in third resist film 43, a third opening 83 corresponding to second opening 82, and a fourth opening 84 in another region, is performed.

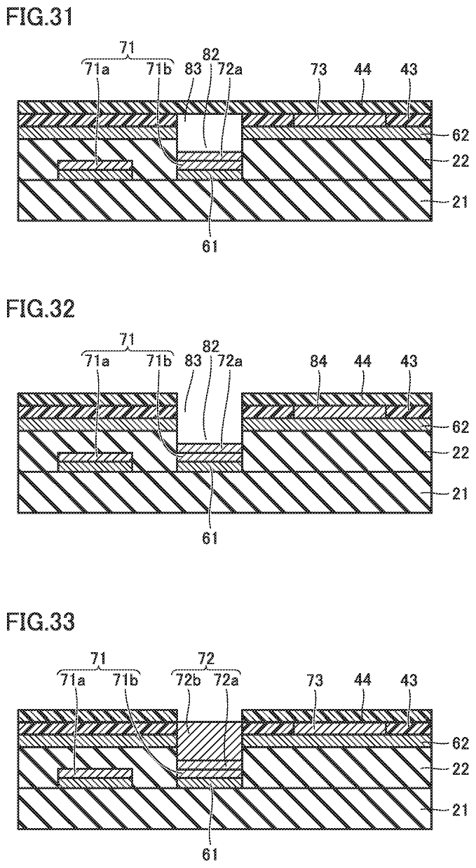

As shown in FIGS. 30 to 33, the step of forming, by plating, a second conductive layer 72 on a part of an upper surface of first conductive layer 71 that is exposed through third opening 83 and second opening 82, and forming, by plating, a third conductive layer 73 on a part of an upper surface of second base metal layer 62 that is exposed from fourth opening 84, is performed. Details of this step are as follows. Initially, as shown in FIG. 30, a part 72a of the second conductive layer is formed, by plating, on a part of the upper surface of first conductive layer 71 that is exposed through third opening 83 and second opening 82, and third conductive layer 73 is formed, by plating, on a part of the upper surface of second base metal layer 62 that is exposed from fourth opening 84. Next, as shown in FIG. 31, fourth resist film 44 is deposited. Fourth resist film 44 in the form of a sheet is prepared and mounted on the upper side of third resist film 43 and third conductive layer 73. Further, as shown in FIG. 32, a part of fourth resist film 44 that is located above third opening 83 and second opening 82 is removed. The partial removal of fourth resist film 44 may be performed by exposure and development. Further, as shown in FIG. 33, a part 72b is formed, by plating, on the upper surface of part 72a of the second conductive layer. In the example illustrated here, the upper surface of part 72b is at the same height as the upper surface of third conductive layer 73. Part 72b may be formed in such a manner that the upper surface of part 72b is located at a higher position than the upper surface of third conductive layer 73. Part 72a and part 72b together form second conductive layer 72.

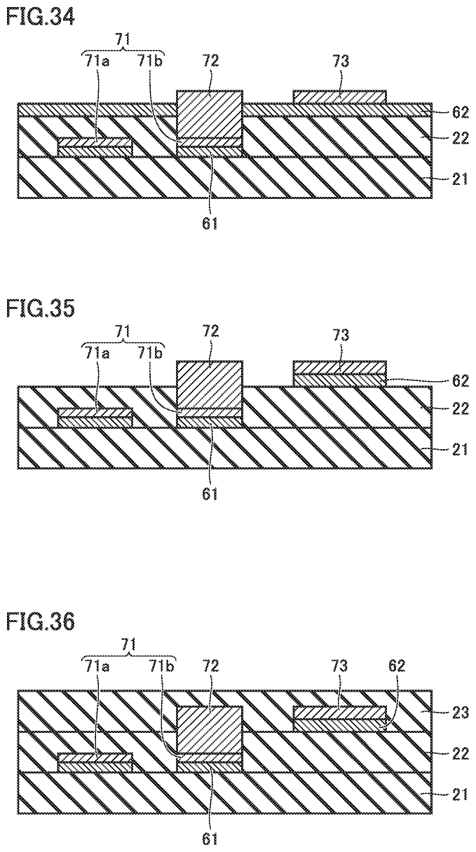

As shown in FIG. 34, the step of removing third resist film 43 is performed. As shown in FIG. 35, the step of removing a part of second base metal layer 62 that is not covered with third conductive layer 73 is performed. As shown in FIG. 36, the step of forming a third insulating layer 23 to cover second insulating layer 22, second conductive layer 72, and third conductive layer 73 is performed.

The resultant structure is fired to thereby obtain multilayer structure 102 shown in FIG. 4. Each of first insulating layer 21, second insulating layer 22, and third insulating layer 23 may either be a resin layer or a ceramic layer. If they are resin layers, the material for the layers may be polyimide resin, for example. If second insulating layer 22 and third insulating layer 23 are resin layers, they can be formed by applying resin paste. If second insulating layer 22 and third insulating layer 23 are ceramic layers, they can be formed by applying ceramic paste. While FIG. 36 shows borderlines between first insulating layer 21, second insulating layer 22, and third insulating layer 23, these lines are indicated for convenience of illustration. The borderlines may disappear after the firing.

In FIG. 36, part 71a of first conductive layer 71 and first base metal layer 61 together form first conductor 31. Second conductive layer 72 and first base metal layer 61 together form third conductor 33. Third conductive layer 73 and second base metal layer 62 together form second conductor 32.

In connection with the present embodiment, an example of manufacturing multilayer structure 102 shown in FIG. 4 is illustrated. The other multilayer structures can also be manufactured by applying a similar approach.

Either the first conductor or the second conductor may be disposed on a surface of the multilayer structure. In this case, a part of the third conductor may be disposed on a surface of the multilayer structure.

In the foregoing, the term “multilayer structure” is used. Multilayer structure refers to a concept that should encompass a multilayer substrate, and also encompass an electronic component produced by stacking certain materials. The concept of multilayer structure also encompasses an electronic component of the stack type, and therefore, this concept also encompasses a filter of the stack type. The stack-type filter may be a stack-type LC filter, for example.

Materials for a ceramic multilayer substrate that is the multilayer structure to which the present disclosure is applied, are described further in detail.

Preferably, a base ceramic layer forming the body of the multilayer structure includes a low-temperature sintered ceramic material.

“Low-temperature sintered ceramic material” refers to a material that can be sintered at a firing temperature of 1000° C. or lower and can be fired simultaneously with Ag, Cu, or the like, among ceramic materials.

The low-temperature sintered ceramic material contained in the base ceramic layer may for example be a glass composite-based low-temperature sintered ceramic material obtained by mixing borosilicate glass with a ceramic material such as quartz, alumina, or forsterite, or a crystallized glass-based low-temperature sintered ceramic material for which used ZnO—MgO—Al₂O₃—SiO₂-based crystallized glass. The low-temperature sintered ceramic material contained in the base ceramic layer may further be a non-glass-based low-temperature sintered ceramic material for which used a BaO—Al₂O₃—SiO₂-based ceramic material or an Al₂O₃—CaO—SiO₂—MgO—B₂O₃-based ceramic material, for example.

An internal interconnection conductor provided inside the body of an electronic component contains an electrically conductive component. “Internal interconnection conductor” herein refers to an internal conductor film and a via hole conductor. The electrically conductive component contained in the internal interconnection conductor may be any metal selected from the group consisting for example of Au, Ag, Cu, Pt, Ta, W, Ni, Fe, Cr, Mo, Ti, Pd, and Ru, or may be an alloy containing, as its main component, one or more different metals selected from the above-specified group. The internal interconnection conductor preferably contains, as an electrically conductive component, Au, Ag or Cu, and more preferably contains Ag or Cu. Au, Ag and Cu have low resistance, and therefore, they are particularly suitable for the case where the ceramic electronic component is applied to radio-frequency applications.

The base ceramic layer forming the body of the multilayer structure may be a ceramic material used for an LC composite component such as multilayer filter.

A first example of the material that satisfies such conditions may for example be a glass-based ceramic material containing Mg₂SiO₄+BaO—Nd₂O₃—TiO₂ as a ceramic filler, at least one of MnCO₃, SiO₂, Al₂O₃, and Mg(OH)₂ as an external additive, and Si—B—Ba—Sr—Ca—Mg—Al—Li—O as a glass-based component. Mg₂SiO₄+BaO—Nd₂O₃—TiO₂ may herein contain, as a main material, either Mg₂SiO₄ or BaO—Nd₂O₃—TiO₂.

A second example of the material that satisfies such conditions may for example be a glass-based ceramic material containing Mg₂SiO₄ as a ceramic filler, at least one of TiO₂ and SrTiO₃ as an external additive, and Si—B—Li—Mg—Sr—Zn—O as a glass-based component.

A third example of the material that satisfies such conditions may for example be a glass-based ceramic material containing SiO₂ as a ceramic filler, at least one of Al₂O₃ and Mg(OH)₂ as an external additive, and Si—B—Ba—Sr—Ca—Mg—Al—Li—O-based and Ba—Al—Si—Zr—Ti—Mg—Mn—O-based components as glass-based components.

In each of the various glass-based ceramic materials specified herein, the total of respective contents of the ceramic filler, the external additive, and the glass-based component(s) is 100 wt %.

The electrically conductive component contained in a baked electrode may for example be any metal selected from the group consisting for example of Cu, Ag, Au, Pt, Ta, W, Ni, Fe, Cr, Mo, Ti, Pd, and Ru, or may be an alloy containing, as its main component, one or more different metals selected from the above-specified group. The baked electrode preferably contains Cu, Ag or Au as an electrically conductive component, and more preferably contains Cu or Ag.

### Embodiment 10

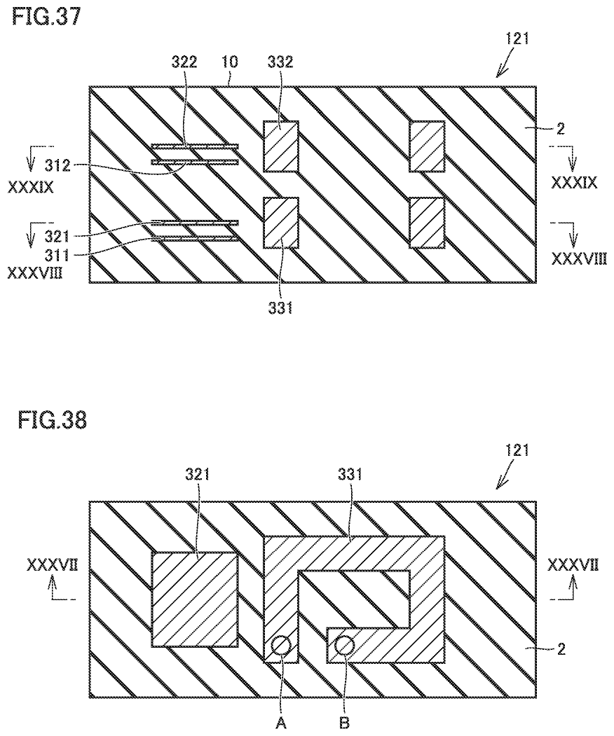

Referring to FIGS. 37 to 39, a multilayer structure according to Embodiment 10 based on the present disclosure is described. In an example illustrated here, a multilayer structure 121 is an electronic component. More specifically, multilayer structure 121 is an LC composite component. Still more specifically, multilayer structure 121 is an LC filter.

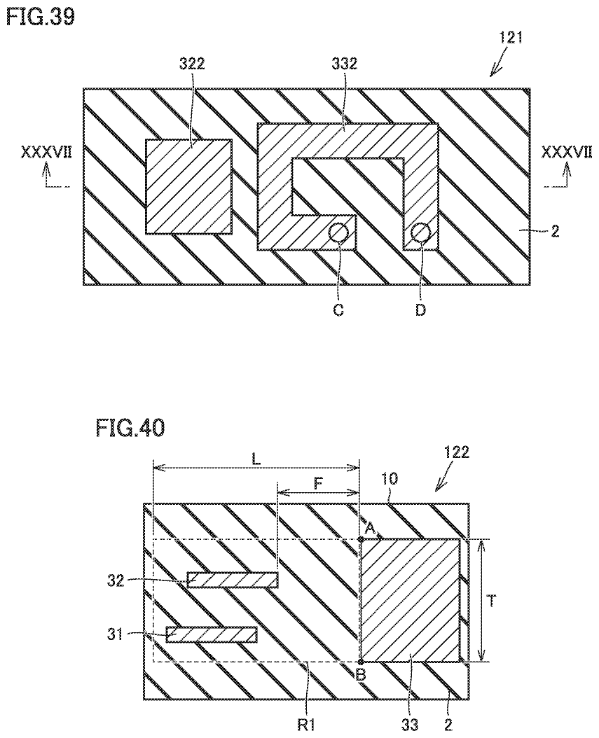

FIG. 37 shows a cross-sectional view of a plane parallel with the stack direction of multilayer structure 121. In FIG. 37, the top-to-bottom direction is the stack direction, i.e., thickness direction. FIG. 38 shows a cross-sectional view along line XXXVIII-XXXVIII in FIG. 37 as seen in the direction of the arrows. FIG. 39 shows a cross-sectional view along line XXXIX-XXXIX in FIG. 37 as seen in the direction of the arrows.

FIG. 37 is also a cross-sectional view along line XXXVII-XXXVII in FIG. 38, and FIG. 37 is also a cross-sectional view along line XXXVII-XXXVII in FIG. 39.

Multilayer structure 121 has a main surface 10. Multilayer structure 121 includes a first conductor 311, a second conductor 321, and a third conductor 331. First conductor 311 extends in parallel with main surface 10. Second conductor 321 extends in parallel with main surface 10 and disposed at a position different from first conductor 311 with respect to the thickness direction of multilayer structure 121. Third conductor 331 has a shape extending in at least any direction as seen in the direction perpendicular to main surface 10. Third conductor 331 is disposed at a position beside both first conductor 311 and second conductor 321. First conductor 311 is at least partially included and second conductor 321 is at least partially included, in a range higher than the lower end of third conductor 331 and lower than the upper end of third conductor 331 in the thickness direction of multilayer structure 121.

First conductor 311 and second conductor 321 are arranged with the insulator interposed in between, to thereby function as a capacitive element, i.e., capacitor. Each of first conductor 311 and second conductor 321 is not a passage through which large current flows, and therefore has a thin thickness in general.

In contrast, third conductor 331 functions as an inductive element, i.e., inductor, provided by the stack structure of the peripheral circuitry. Third conductor 331 is a passage through which electric current flows directly, and is therefore required to have a larger cross section as a conductor, in order to prevent signal attenuation.

Signal attenuation herein refers to insertion loss. From part A of third conductor 331, a via connection to a lower layer is made. From part B of third conductor 331, a via connection to part C of third conductor 332 shown in FIG. 39 is made.

The value of the capacitance and the value of the inductance of these elements directly affect properties related to blockage and passage by the filter, and therefore, desirably unintended variation of the parasitic capacitance is reduced as much as possible.

In the present embodiment, advantageous effects as illustrated in connection with Embodiment 1 are obtained between first conductor 311, second conductor 321, and third conductor 331. Specifically, as seen in a cross section perpendicular to main surface 10, first conductor 311 is at least partially included and second conductor 321 is at least partially included in a range higher than the lower end of third conductor 331 and lower than the upper end of third conductor 331, and therefore, deformation of first conductor 311 and second conductor 321 is suppressed. Thus, generation of unintended parasitic components during firing can be suppressed.

Multilayer structure 121 further includes a first conductor 312, a second conductor 322, and third conductor 332. Between first conductor 312, second conductor 322, and third conductor 332 as well, the relation in terms of the position and the cross-sectional size is held, similarly to the above-described relation between first conductor 311, second conductor 321, and third conductor 331. From part D of third conductor 332, a via connection to a higher layer is made. From the relation between first conductor 312, second conductor 322, and third conductor 332 as well, advantageous effects similar to the above-described ones derived from the relation between first conductor 311, second conductor 321, and third conductor 331 are obtained.

### Embodiment 11

Referring to FIGS. 40 to 41, a multilayer structure according to Embodiment 11 based on the present disclosure is described. In an example illustrated here, multilayer structure 122 is a multilayer substrate, and more specifically a ceramic multilayer substrate. This is given merely by way of example. Multilayer structure 122 may be a resin multilayer substrate, or an electronic component.

The effect of suppressing deformation of the first conductor and the second conductor by the presence of the third conductor is greater, as the positions of the first conductor and the second conductor are closer to the position of the third conductor. This effect is also greater as the positions of the first conductor and the second conductor are closer to the center, in the thickness direction, of the third conductor.

FIG. 40 shows a cross-sectional view of multilayer structure 122. Third conductor 33 has thickness T. In the cross-sectional view, rectangle R1 having vertical side AB and horizontal length L is defined, where point A and point B are respectively an upper end and a lower end of the side of third conductor 33 that is relatively closer to first conductor 31 and second conductor 32, and L is a length extending from third conductor 33 away from third conductor 33. Length L is six times as large as T. As seen in this cross-sectional view, at least one of first conductor 31 and second conductor 32 is at least partially located within the range of rectangle R1. For example, as shown in FIG. 40, F≤L=6T is satisfied, where F is the distance from third conductor 33 to one of first conductor 31 and second conductor 32 that is relatively closer to third conductor 33. While second conductor 32 is located closer to third conductor 33 than first conductor 31, this is given merely by way of example, and first conductor 31 may be located closer to third conductor 33 than second conductor 32, or the distance from first conductor 31 to third conductor 33 may be identical to the distance from second conductor 32 to third conductor 33.

If third conductor 33 as seen in the cross-sectional view has a rounded shape, points A and B may each be defined as the point where respective extended lines of adjacent sides cross each other as shown in FIG. 41.

In the present embodiment, at least one of first conductor 31 and second conductor 32 is at least partially located within the range of rectangle R1, and therefore, first conductor 31 and second conductor 32 are sufficiently close to third conductor 33, which effectively suppresses deformation of first conductor 31 and second conductor 32 and thereby suppresses generation of unintended parasitic components during firing.

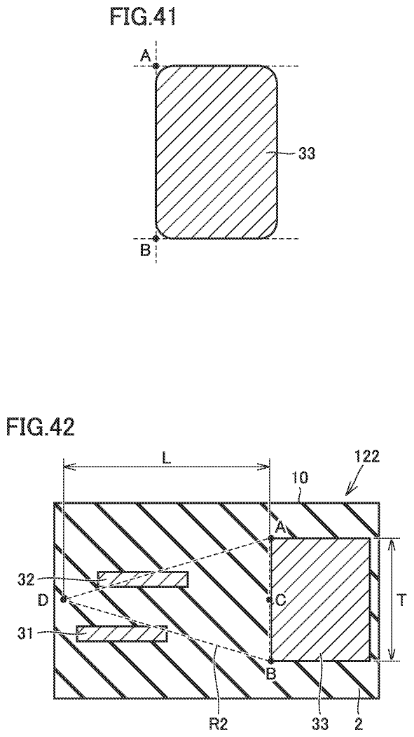

A further preferred condition is described with reference to FIG. 42. In the cross-sectional view, triangle ABD is defined, where AB is a line segment, C is the midpoint of line segment AB, D is a point located away from third conductor 33 by distance L, in the direction perpendicular to line segment AB. L is six times as large as T. Triangle ABD can be identified as an equilateral triangle having base length T and height L. Preferably, as seen in this cross-sectional view, at least one of first conductor 31 and second conductor 32 is at least partially located within the range of triangle ABD. When this condition is satisfied, deformation of first conductor 31 and second conductor 32 is suppressed more effectively, and therefore, generation of unintended parasitic components during firing can further be suppressed.

While triangle ABD is defined here to satisfy L=6T, this condition is more preferably L=3T.

More than one of the above-described embodiments may be combined appropriately and employed in the form of the combination.

The embodiments disclosed herein are given by way of illustration in all respects, not by way of limitation. The scope of the present disclosure is defined by claims, and encompasses all modifications and variations equivalent in meaning and scope to the claims.

2 insulator; 10 main surface; 13 range; 21 first insulating layer; 22 second insulating layer; 23 third insulating layer; 31, 311, 312 first conductor; 32, 321, 322 second conductor; 33, 331, 332 third conductor; 33a, 33b part (of third conductor); 34 fourth conductor; 41 first resist film; 42 second resist film; 43 third resist film; 44 fourth resist film; 61 first base metal layer; 62 second base metal layer; 71 first conductive layer; 71a, 71b part (of first conductive layer); 72 second conductive layer; 72a, 72b part (of second conductive layer); 73 third conductive layer; 81 first opening; 82 second opening; 83 third opening; 84 fourth opening; 101, 102, 103, 104, 105, 106, 107, 108, 109, 110, 121, 122 multilayer structure

1. A multilayer structure having a main surface, the multilayer structure comprising:
a first conductor extending in parallel with the main surface;
a second conductor extending in parallel with the main surface and disposed at a different position from the first conductor with respect to a thickness direction of the multilayer structure; and
a third conductor having a shape extending in at least any direction as seen in a direction perpendicular to the main surface, wherein
within a range higher than a lower end of the third conductor and lower than an upper end of the third conductor in the thickness direction of the multilayer structure, at least a part of the first conductor is included and at least a part of the second conductor is included.

2. The multilayer structure according to claim 1, wherein within the range higher than the lower end of the third conductor and lower than the upper end of the third conductor in the thickness direction of the multilayer structure, the first conductor is entirely included and the second conductor is entirely included.

3. The multilayer structure according to claim 1, wherein the first conductor and the second conductor at least partially overlap each other as seen in the direction perpendicular to the main surface.

4. The multilayer structure according to claim 1, wherein at least one of the first conductor and the second conductor is connected to the third conductor.

5. The multilayer structure according to claim 1, wherein the multilayer structure is a multilayer substrate.

6. The multilayer structure according to claim 1, wherein the multilayer structure is an electronic component.

7. The multilayer structure according to claim 6, wherein the electronic component is an LC composite component.

8. A method for manufacturing a multilayer structure for obtaining the multilayer structure according to claim 1, the method comprising:
forming a first base metal layer on an upper surface of a first insulating layer;
depositing a first resist film on an upper side of the first base metal layer;
partially exposing the first base metal layer by forming a first opening in the first resist film;
forming, by plating, a first conductive layer on a part of an upper surface of the first base metal layer exposed from the first opening;
removing the first resist film;
removing a part of the first base metal layer not covered with the first conductive layer;
depositing a second resist film on only a part of the first conductive layer;
forming a second insulating layer covering the first insulating layer and the first conductive layer and exposing the second resist film;
forming, in the second insulating layer, a second opening exposing a part of the first conductive layer, by removing the second resist film;
forming a second base metal layer on an upper surface of the second insulating layer;
depositing a third resist film on an upper side of the second base metal layer;
forming, in the third resist film, a third opening corresponding to the second opening, and a fourth opening in another region;
forming, by plating, a second conductive layer on a part of an upper surface of the first conductive layer exposed through the third opening and the second opening and forming, by plating, a third conductive layer on a part of an upper surface of the second base metal layer exposed from the fourth opening;
removing the third resist film;
removing a part of the second base metal layer not covered with the third conductive layer; and
forming a third insulating layer covering the second insulating layer, the second conductive layer, and the third conductive layer.

9. The multilayer structure according to claim 1, wherein the third conductor is not exposed to an outer surface of the multilayer structure.

10. The multilayer structure according to claim 7, wherein the third conductor functions as an inductor, provided by a stack structure of a peripheral circuitry.

11. The multilayer structure according to claim 2, wherein the first conductor and the second conductor at least partially overlap each other as seen in the direction perpendicular to the main surface.

12. The multilayer structure according to claim 2, wherein at least one of the first conductor and the second conductor is connected to the third conductor.

13. The multilayer structure according to claim 3, wherein at least one of the first conductor and the second conductor is connected to the third conductor.

14. The multilayer structure according to claim 2, wherein the multilayer structure is a multilayer substrate.

15. The multilayer structure according to claim 3, wherein the multilayer structure is a multilayer substrate.

16. The multilayer structure according to claim 4, wherein the multilayer structure is a multilayer substrate.

17. The multilayer structure according to claim 2, wherein the multilayer structure is an electronic component.

18. The multilayer structure according to claim 3, wherein the multilayer structure is an electronic component.

19. The multilayer structure according to claim 4, wherein the multilayer structure is an electronic component.

20. A method for manufacturing a multilayer structure for obtaining the multilayer structure according to claim 2, the method comprising:
forming a first base metal layer on an upper surface of a first insulating layer;
depositing a first resist film on an upper side of the first base metal layer;
partially exposing the first base metal layer by forming a first opening in the first resist film;
forming, by plating, a first conductive layer on a part of an upper surface of the first base metal layer exposed from the first opening;
removing the first resist film;
removing a part of the first base metal layer not covered with the first conductive layer;
depositing a second resist film on only a part of the first conductive layer;
forming a second insulating layer covering the first insulating layer and the first conductive layer and exposing the second resist film;
forming, in the second insulating layer, a second opening exposing a part of the first conductive layer, by removing the second resist film;
forming a second base metal layer on an upper surface of the second insulating layer;
depositing a third resist film on an upper side of the second base metal layer;
forming, in the third resist film, a third opening corresponding to the second opening, and a fourth opening in another region;
forming, by plating, a second conductive layer on a part of an upper surface of the first conductive layer exposed through the third opening and the second opening and forming, by plating, a third conductive layer on a part of an upper surface of the second base metal layer exposed from the fourth opening;
removing the third resist film;
removing a part of the second base metal layer not covered with the third conductive layer; and
forming a third insulating layer covering the second insulating layer, the second conductive layer, and the third conductive layer.
